(19) United States
(12) Patent Application Publication
(10) Pub. No.: US 2011/0036292 A1
(43) Pub. Date: Feb. 17, 2011

(54) Manufacturing Apparatus For Depositing A Material And An Electrode For Use Therein

(76) Inventors: Max Dehtiar, Midland, MI (US); David Hillabrand, Midland, MI (US); Theodore Knapp, Midland, MI (US); Keith Mccoy, Midland, MI (US); Michael Molnar, Freeland, MI (US)

Correspondence Address: HOWARD & HOWARD ATTORNEYS PLLC, 450 West Fourth Street, Royal Oak, MI, 48067, US

(21) Appl. No.: 12/937,790

(22) PCT Filed: Apr. 13, 2009
(86) PCT No.: PCT/US09/02289

§ 371 Date: Oct. 14, 2010

Related U.S. Application Data
(60) Provisional application No. 61/044,666, filed on Apr. 14, 2008.

(51) Int. Cl. C23C 16/50

(52) U.S. Cl. 118/723 E

(57) ABSTRACT

The present invention relates to a manufacturing apparatus for deposition of a material on a carrier body and an electrode for use with the manufacturing apparatus. Typically, the carrier body has a first end and a second end spaced from each other. A socket is disposed at each of the end of the carrier body. The apparatus includes a housing that defines a chamber. At least one electrode is disposed through the housing for receiving the socket. The electrode includes an interior surface that defines a channel. The electrode heats the carrier body to a necessary deposition temperature by direct passage of electrical current to the carrier body. A coolant is in fluid communication with the channel of the electrode for reducing the temperature of the electrode. A channel coating is disposed in the interior surface of the electrode for preventing loss of heat transfer between the coolant and the interior surface.

### RELATED APPLICATIONS

This application claims priority to and all advantages of U.S. Provisional Patent Application No. 61/044,666, which was filed on Apr. 14, 2008.

### FIELD OF THE INVENTION

The present invention relates to a manufacturing apparatus. More specifically, the present invention relates to an electrode utilized within the manufacturing apparatus.

### BACKGROUND OF THE INVENTION

Manufacturing apparatuses for the deposition of a material on a carrier body are known in the art. Such manufacturing apparatuses comprise a housing that defines a chamber. Generally, the carrier body is substantially U-shaped having a first end and a second end spaced from each other. Typically, a socket is disposed at each end of the carrier body. Generally, two or more electrodes are disposed within the chamber for receiving the respective socket disposed at the first end and the second end of the carrier body. The electrode also includes a contact region, which supports the socket and, ultimately, the carrier body to prevent the carrier body from moving relative to the housing. The contact region is the portion of the electrode adapted to be in direct contact with the socket and that provides a primary current path from the electrode to the socket and into the carrier body.

A power supply device is coupled to the electrode for supplying electrical current to the carrier body. The electrical current heats both the electrode and the carrier body. The electrode and the carrier body each have a temperature with the temperature of the carrier body being heated to a deposition temperature. A processed carrier body is formed by depositing the material on the carrier body.

As known in the art, variations exist in the shape of the electrode and socket to account for thermal expansion of the material deposited on the carrier body as the carrier body is heated to the deposition temperature. One such method utilizes a flat head electrode and a socket in the form of a graphite sliding block. The graphite sliding block acts as a bridge between the carrier body and the flat head electrode. The weight of the carrier body and the graphite block acting on the contact region reduces the contact resistance between the graphite sliding block and the flat head electrode. Another such method involves the use of a two-part electrode. The two-part electrode includes a first half and a second half for compressing the socket. A spring element is coupled to the first half and the second half of the two-part electrode for providing a force to compress the socket. Another such method involves the use of an electrode defining a cup with the contact region located within the cup of the electrode. The socket is adapted to fit into the cup of the electrode and contacts the contact region located within the cup of the electrode. Alternatively, the electrode may define the contact region on an outer surface thereof without defining a cup, and the socket may be structured as a cap that fits over the top of the electrode for contacting the contact region located on the outer surface of the electrode.

A circulating system is typically coupled to the electrode for circulating a coolant through the electrode. The coolant is circulated for preventing the temperature of the electrode from reaching the deposition temperature to inhibit the material from depositing on the electrode. Controlling the temperature of the electrode also prevents sublimation of the material of the electrode and hence reduces the likelihood of contamination of the carrier body.

The electrode includes an exterior surface and an interior surface having a terminal end and defining a channel. A fouling of the electrode occurs on the interior surface of the electrode due to the interaction between the coolant and the interior surface. The cause of the fouling is dependant on the type of coolant used. For example, minerals can be suspended in the coolant (e.g, when the coolant is water) and the minerals can be deposited on the interior surface during the heat exchange between the coolant and the electrode. Additionally, the deposits can build up over time independent of the existence of minerals within the coolant. Alternatively, the fouling can be in the form of an organic film deposited on the interior surface of the electrode. Additionally, the fouling can form as a result of oxidation of the interior surface of the electrode, for example, when the coolant is deionized water or other coolants. The exact deposits that form may also depend on various factors, including temperatures to which the interior surface of the electrode are heated. The fouling of the electrode decreases the heat transfer capability between the coolant and the electrode.

The electrode must be replaced when one or more of the following conditions occur: first, when the metal contamination of the material being deposited upon the carrier body exceeds a threshold level; second, when fouling of the contact region of the electrode in the chamber causes the connection between the electrode and the socket to become poor; and third, when excessive operating temperatures for the electrode are required due to fouling of the contact region on the electrode. The electrode has a life determined by the number of the carrier bodies the electrode can process before one of the above occurs.

In view of the foregoing problems related to fouling of the electrode, there remains a need to at least delay the fouling of the electrode for maintaining the heat transfer between the electrode and the coolant in the channel, thereby improving the productivity and increase the life of the electrode.

### SUMMARY OF THE INVENTION AND ADVANTAGES

The present invention relates to a manufacturing apparatus for deposition of a material on a carrier body and an electrode for use with the manufacturing apparatus. The carrier body has a first end and a second end spaced from each other. A socket is disposed at each of the ends of the carrier body.

The manufacturing apparatus includes a housing that defines a chamber. An inlet is defined through the housing for introducing a gas into the chamber. An outlet is also defined through the housing for exhausting the gas from the chamber. At least one electrode is disposed through the housing with the electrode at least partially disposed within the chamber for receiving the socket. The electrode has an interior surface that defines a channel. A power supply device is coupled to the electrode for providing an electrical current to the electrode. A circulating system is disposed within the channel for circulating a coolant through the electrode.

A channel coating is disposed on the interior surface of the electrode for maintaining thermal conductivity between the electrode and the coolant. One advantage of the channel coating is that it is possible to delay fouling of the electrode by resisting the formation of deposits that can form over time due to the interaction between the coolant and the interior surface of the electrode. By delaying fouling, the life of the electrode is extended resulting in a lower production cost and reduced production cycle time of the processed carrier bodies.

### BRIEF DESCRIPTION OF THE DRAWINGS

Other advantages of the present invention will be readily appreciated, as the same becomes better understood by reference to the following detailed description when considered in connection with the accompanying drawings wherein:

FIG. 1 is a cross-sectional view of a manufacturing apparatus for depositing a material on a carrier body;

FIG. 2 is a perspective view of an electrode defining a cup utilized with the manufacturing apparatus of FIG. 1;

FIG. 3 is a cross-sectional view of the electrode taken along line 3-3 in FIG. 2 with the electrode having an interior surface defining a channel and including a terminal end;

FIG. 3A is an enlarged cross-sectional view of a portion the electrode of FIG. 3 with the terminal end having a flat configuration;

FIG. 3B is an enlarged cross-sectional view of a portion of the electrode of FIG. 3 with an alternative embodiment of the terminal end having a cone configuration;

FIG. 3C is an enlarged cross-sectional view of a portion of the electrode of FIG. 3 with an alternative embodiment of the terminal end having a elliptical configuration;

FIG. 3D is an enlarged cross-sectional view of a portion of the electrode of FIG. 3 with an alternative embodiment of the terminal end having an inverted cone configuration;

FIG. 4 is a cross-sectional view of the electrode of FIG. 3 with a portion of a circulation system connected to a first end of the electrode;

FIG. 5 is a cross-sectional view of another embodiment of the electrode of FIGS. 2 and 3 with a shaft coating, a head coating and a contact region coating disposed on the electrode; and

FIG. 6 is a cross-sectional view of the manufacturing apparatus of FIG. 1 during the deposition of the on the carrier body.

### DETAILED DESCRIPTION OF THE INVENTION

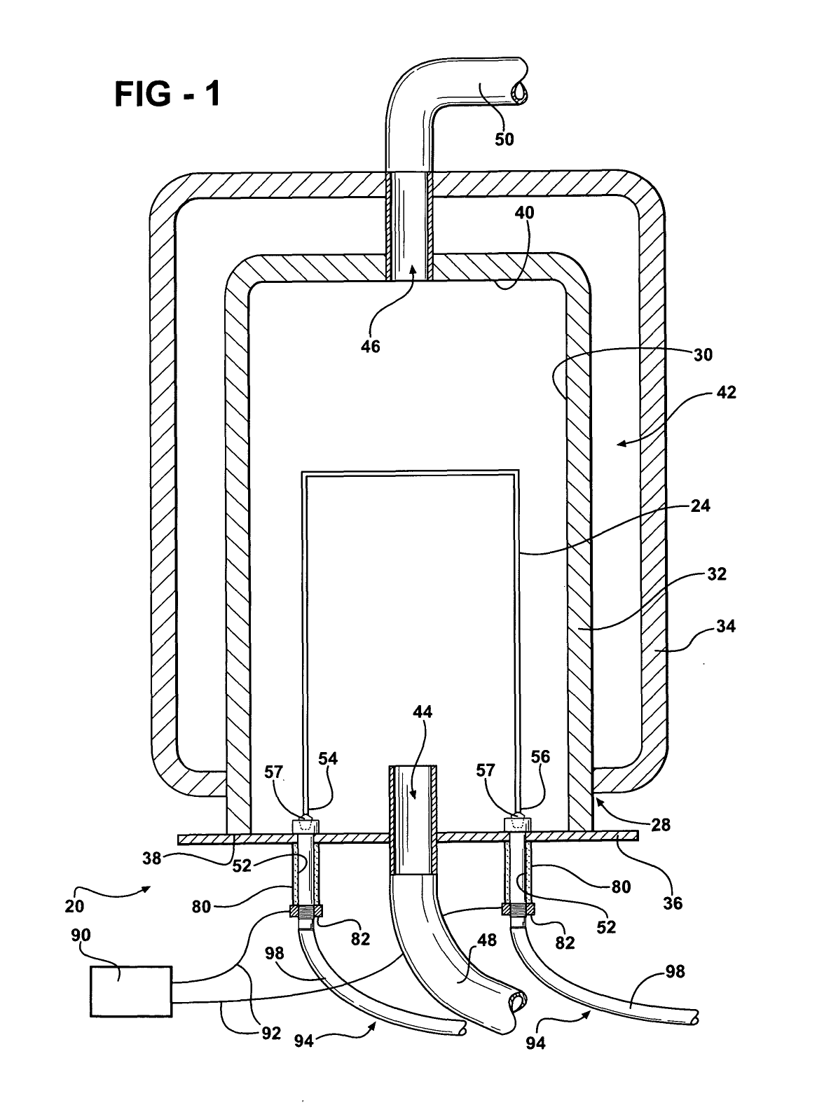

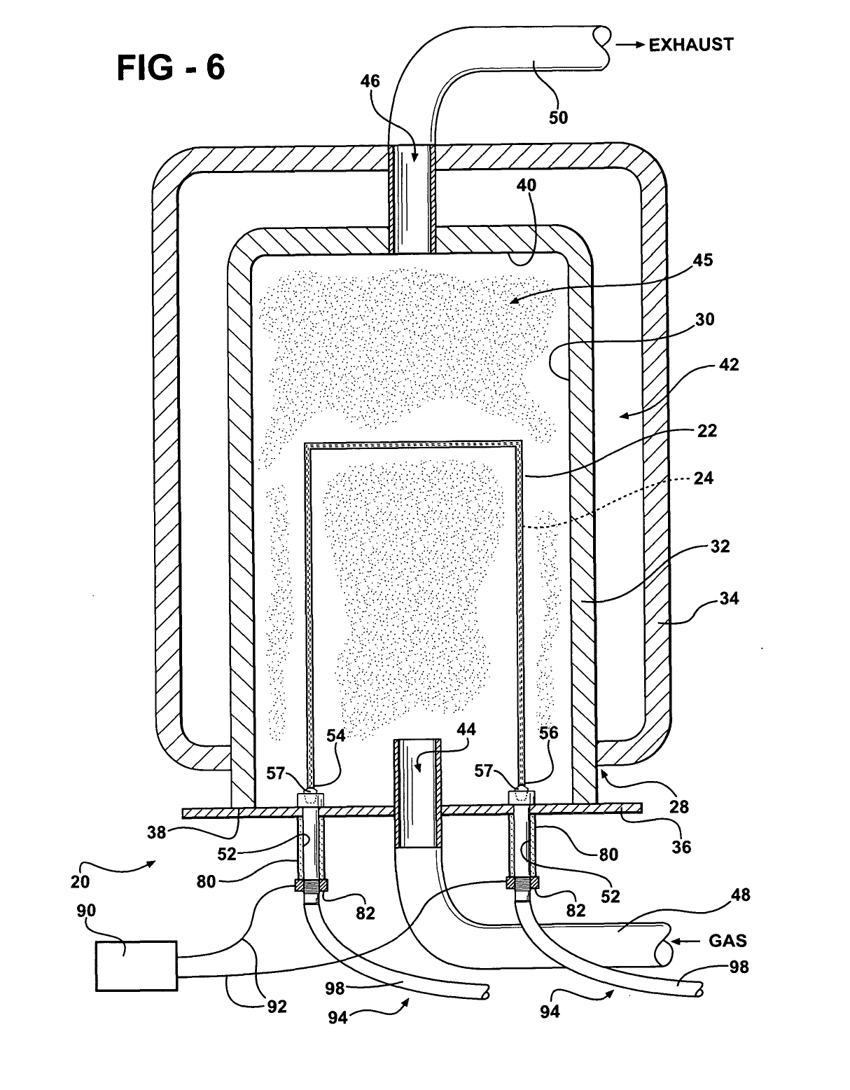

Referring to the Figures, wherein like numerals indicate like or corresponding parts throughout the several views, a manufacturing apparatus 20 for deposition of a material 22 on a carrier body 24 is shown in FIGS. 1 and 6. In one embodiment, the material 22 to be deposited is silicon; however, it is to be appreciated that the manufacturing apparatus 20 can be used to deposit other materials on the carrier body 24 without deviating from the scope of the subject invention.

Typically, with methods of chemical vapor deposition known in the art, such as the Siemens method, the carrier body 24 is substantially U-shaped and has a first end 54 and a second end 56 spaced and parallel to each other. A socket 57 is disposed at each of the first end 54 and the second end 56 of the carrier body 24.

The manufacturing apparatus 20 includes a housing 28 that defines a chamber 30. Typically, the housing 28 comprises an interior cylinder 32, an outer cylinder 34, and a base plate 36. The interior cylinder 32 includes an open end 38 and a closed end 40 spaced from each other. The outer cylinder 34 is disposed about the interior cylinder 32 to define a void 42 between the interior cylinder 32 and the outer cylinder 34, typically serving as a jacket to house a circulated cooling fluid (not shown). It is to be appreciated by those skilled in the art that the void 42 can be, but is not limited to, a conventional vessel jacket, a baffled jacket, or a half-pipe jacket.

The base plate 36 is disposed on the open end 38 of the interior cylinder 32 to define the chamber 30. The base plate 36 includes a seal (not shown) disposed in alignment with the interior cylinder 32 for sealing the chamber 30 once the interior cylinder 32 is disposed on the base plate 36. In one embodiment, the manufacturing apparatus 20 is a Siemens type chemical vapor deposition reactor.

The housing 28 defines an inlet 44 for introducing a gas 45 into the chamber 30 and an outlet 46 for exhausting the gas 45 from the chamber 30 as shown in FIG. 6. Typically, an inlet pipe 48 is connected to the inlet 44 for delivering the gas 45 to the housing 28 and an exhaust pipe 50 is connected to the outlet 46 for removing the gas 45 from the housing 28. The exhaust pipe 50 can be jacketed with a cooling fluid such as water, a commercial heat transfer fluid, or other heat transfer fluid.

At least one electrode 52 is disposed through the housing 28 for coupling with the socket 57. In one embodiment, as shown in FIGS. 1 and 6, the at least one electrode 52 includes a first electrode 52 disposed through the housing 28 for receiving the socket 57 of the first end 54 of the carrier body 24 and a second electrode 52 disposed through the housing 28 for receiving the socket 57 of the second end 56 of the carrier body 24. It is to be appreciated that the electrode 52 can be any type of electrode known in the art such as, for example, a flat head electrode, a two-part electrode or a cup electrode. Further, the at least one electrode 52 is at least partially disposed within the chamber 30. In one embodiment, the electrode 52 is disposed through the base plate 36.

The electrode 52 comprises an electrically conductive material having a minimum electrical conductivity at room temperature of at least 14×10⁶ Siemens/meter or S/m. For example, the electrode 52 can comprise at least one of copper, silver, nickel, Inconel and gold, each of which meets the conductivity parameters set forth above. Additionally, the electrode 52 can comprise an alloy that meets the conductivity parameters set forth above. Typically, the electrode 52 comprises electrically conductive material having a minimum electrical conductivity at room temperature of about 58×10⁶ S/m. Typically, the electrode 52 comprises copper and the copper is typically present in an amount of about 100% by weight based on the weight of the electrode 52. The copper can be oxygen-free electrolytic copper grade UNS 10100.

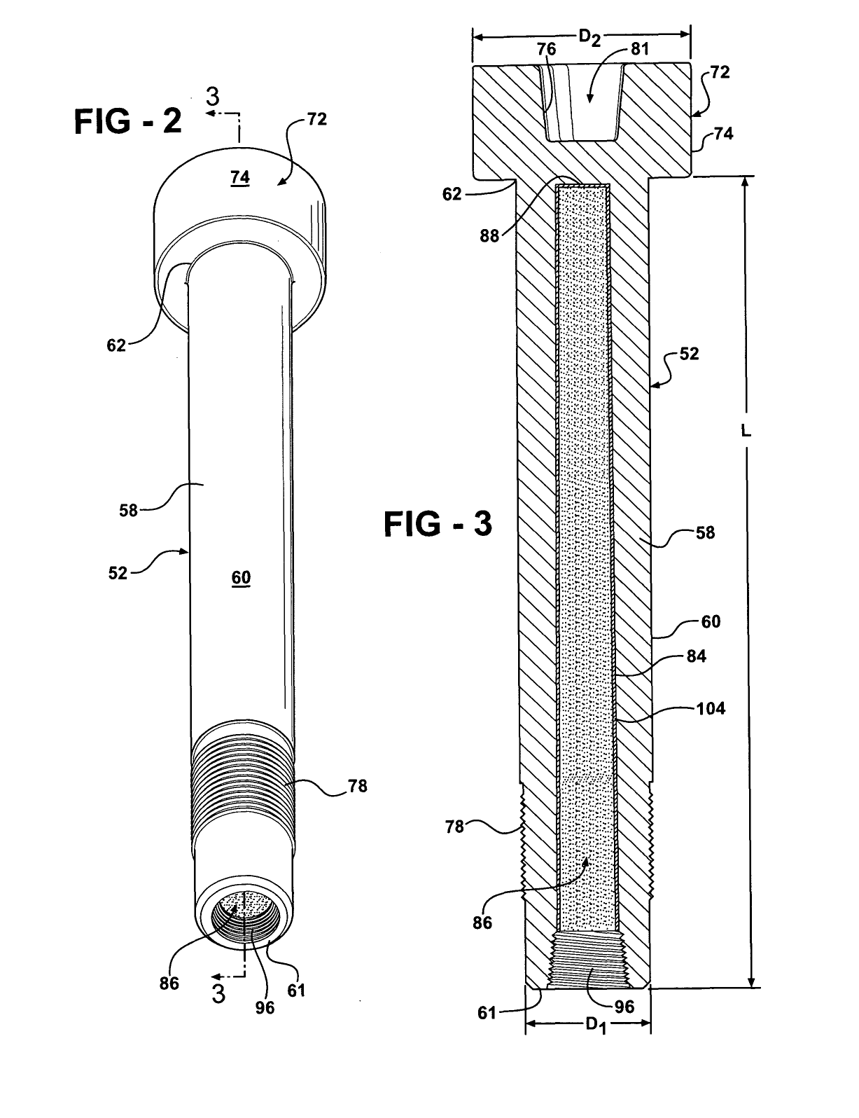

Referring also to FIGS. 2, 3, 4, and 5 in one embodiment the electrode 52 includes a shaft 58 that has an exterior surface 60 disposed between a first end 61 and a second end 62. In one embodiment, the shaft 58 has a circular cross sectional shape resulting in a cylindrically-shaped shaft and defines a diameter D₁. However, it is to be appreciated that the shaft 58 can have a rectangular, a triangular, or an elliptical cross sectional shape without deviating from the subject invention.

The electrode 52 can also include a head 72 disposed on the shaft 58. It is to be appreciated that the head 72 can be integral to the shaft 58. The head 72 has an exterior surface 74 defining a contact region 76 for receiving the socket 57. Typically, the head 72 of the electrode 52 defines a cup 81 and the contact region 76 is located within the cup 81. It is to be appreciated by those skilled in the art that the method of connecting the carrier body 24 to the electrode 52 can vary between applications without deviating from the subject invention. For example, in one embodiment, such as for flat head electrodes (not shown), the contact region can merely be a top, flat surface on the head 72 of the electrode 52 and the socket 57 can define a socket cup (not shown) that fits over the head 72 of the electrode 52 for contacting the contact region. Alternatively, although not shown, the head 72 may be absent from the ends 61, 62 of the shaft 58. In this embodiment, the electrode 52 may define the contact region on the exterior surface 60 of the shaft 58, and the socket 57 may be structured as a cap that fits over the shaft 58 of the electrode 52 for contacting the contact region 76 located on the exterior surface 60 of the shaft 58.

The socket 57 and the contact region 76 can be designed so that the socket 57 can be removed from the electrode 52 when the carrier body 24 is processed and is harvested from the manufacturing apparatus 20. Typically, the head 72 defines a diameter D₂ that is greater than the diameter D₁ of the shaft 58. The base plate 36 defines a hole (not numbered) for receiving the shaft 58 of the electrode 52 such that the head 72 of the electrode 52 remains within the chamber 30 for sealing the chamber 30.

A first set of threads 78 can be disposed on the exterior surface 60 of the electrode 52. Referring back to FIGS. 1 and 6, a dielectric sleeve 80 is typically disposed around the electrode 52 for insulating the electrode 52. The dielectric sleeve 80 can comprise a ceramic. A nut 82 is disposed on the first set of threads 78 for compressing the dielectric sleeve 80 between the base plate 36 and the nut 82 to secure the electrode 52 to the housing 28. It is to be appreciated that the electrode 52 can be secured to the housing 28 by other methods, such as by a flange, without deviating from the scope of the subject invention.

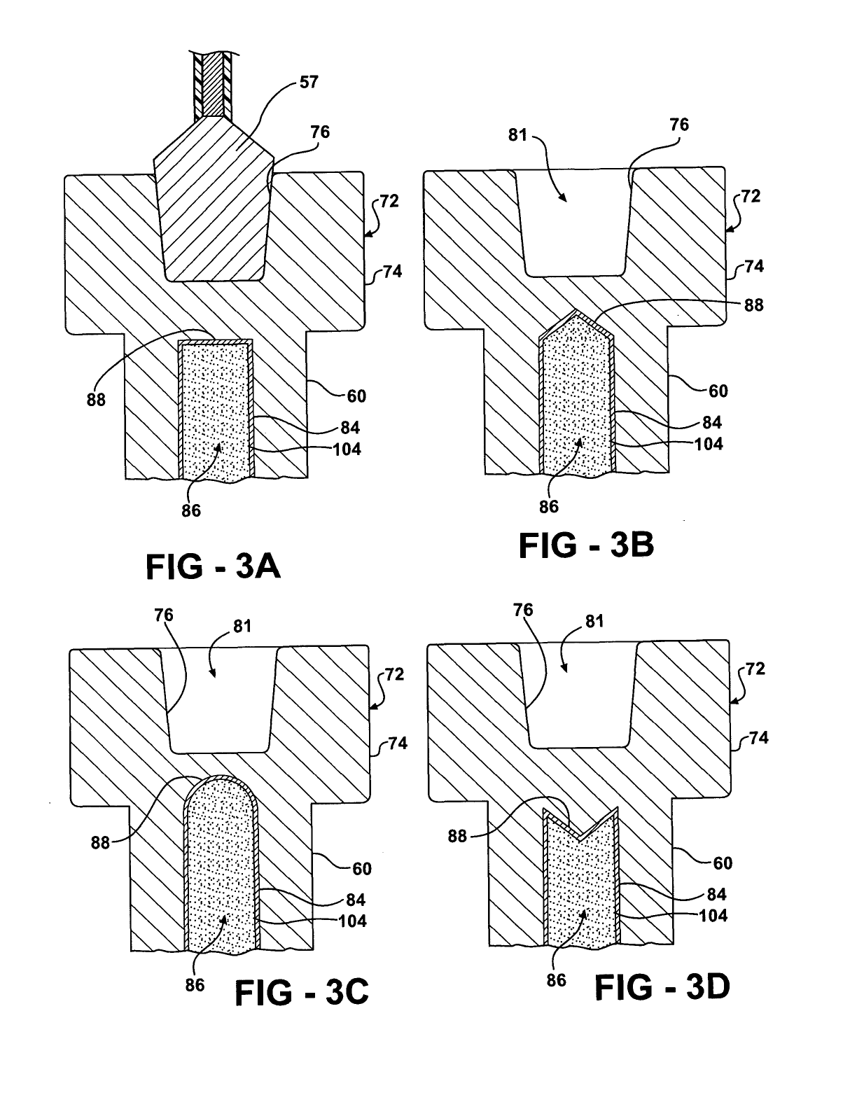

Typically, at least one of the shaft 58 and the head 72 includes an interior surface 84 defining a channel 86. Generally, the first end 61 is an open end of the electrode 52 and defines a hole (not numbered) for allowing access to the channel 86. The interior surface 84 includes a terminal end 88 spaced from the first end 61 of the shaft 58. The terminal end 88 is generally flat and parallel to the first end 61 of the electrode 52. The terminal end 88 can have a flat configuration (as shown in FIG. 3A), a cone-shaped configuration (as shown in FIG. 3B), an ellipse-shaped configuration (as shown in FIG. 3C), or an inverted cone-shaped configuration (as shown in FIG. 3D). The channel 86 has a length L that extends from the first end 61 of the electrode 52 to the terminal end 88. It is to be appreciated that the terminal end 88 can be disposed within the shaft 58 of the electrode 52 or the terminal end 88 can be disposed within the head 72 of the electrode 52, when present, without deviating from the subject invention.

The manufacturing apparatus 20 further includes a power supply device 90 coupled to the electrode 52 for providing an electrical current. Typically, an electric wire or cable 92 couples the power supply device 90 to the electrode 52. In one embodiment, the electric wire 92 is connected to the electrode 52 by disposing the electric wire 92 between the first set of threads 78 and the nut 82. It is to be appreciated that the connection of the electric wire 92 to the electrode 52 can be accomplished by different methods. The electrode 52 has a temperature, which is modified by passage of the electrical current there through resulting in a heating of the electrode 52 and thereby establishing an operating temperature of the electrode 52. Such heating is known to those skilled in the art as Joule heating. In particular, the electrical current passes through the electrode 52, through the socket 57 and through the carrier body 24 resulting in the Joule heating of the carrier body 24. Additionally, the Joule heating of the carrier body 24 results in a radiant/convective heating of the chamber 30. The passage of electrical current through the carrier body 24 establishes an operating temperature of the carrier body 24. Heat generated from the carrier body 24 is conducted through the socket 57 and into the electrode 52, which further increases the operating temperature of the electrode 52.

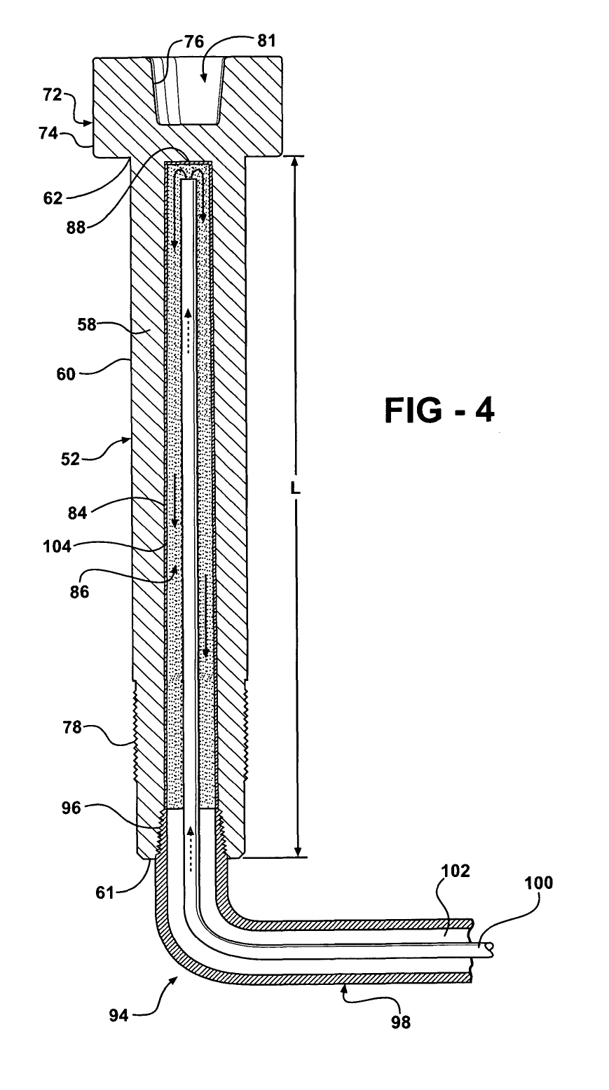

Referring to FIG. 4, the manufacturing apparatus 20 can also include a circulating system 94 at least partially disposed within the channel 86 of the electrode 52. It is to be appreciated that a portion of the circulating system 94 can be disposed outside the channel 86. A second set of threads 96 can be disposed on the interior surface 84 of the electrode 52 for coupling the circulating system 94 to the electrode 52. However, it is to be appreciated by those skilled in the art that other fastening methods, such as use of flanges or couplings, can be used to couple the circulating system 94 to the electrode 52.

The circulating system 94 includes a coolant in fluid communication with the channel 86 of the electrode 52 for reducing the temperature of the electrode 52. In one embodiment, the coolant is water; however, it is to be appreciated that the coolant can be any fluid designed to reduce heat through circulation without deviating from the subject invention. Moreover, the circulating system 94 also includes a hose 98 coupled between the electrode 52 and a reservoir (not shown). The hose 98 includes an inner tube 100 and an outer tube 102. It is to be appreciated that the inner tube 100 and the outer tube 102 can be integral to the hose 98 or, alternatively, the inner tube 100 and the outer tube 102 can be attached to the hose 98 by utilizing couplings (not shown). The inner tube 100 is disposed within the channel 86 and extends a majority of the length L of the channel 86 for circulating the coolant within the electrode 52.

The coolant within the circulating system 94 is under pressure to force the coolant through the inner tube 100 and the outer tubes 102. Typically, the coolant exits the inner tube 100 and is forced against the terminal end 88 of the interior surface 84 of the electrode 52 and subsequently exits the channel 86 via the outer tube 102 of the hose 98. It is to be appreciated that reversing the flow configuration such that the coolant enters the channel 86 via the outer tube 102 and exits the channel 86 via the inner tube 100 is also possible. It is also to be appreciated by those skilled in the art of heat transfer that the configuration of the terminal end 88 influences the rate of heat transfer due to the surface area and proximity to the head 72 of the electrode 52. As set forth above, the different geometric configurations of the terminal end 88 result in different convective heat transfer coefficients between the electrode 52 and the coolant for the same circulation flow rate.

Referring to FIGS. 2 through 4, a channel coating 104 can be disposed on the interior surface 84 of the electrode 52 for maintaining the thermal conductivity between the electrode 52 and the coolant. Generally, the channel coating 104 has a higher resistance to corrosion that is caused by the interaction of the coolant with the interior surface 84 as compared to the resistance to corrosion of the electrode 52. The channel coating 104 typically includes a metal that resists corrosion and that inhibits buildup of deposits. For example, the channel coating 104 can comprise at least one of silver, gold, nickel, and chromium, such as a nickel/silver alloy. Typically, the channel coating 104 is nickel. The channel coating 104 has a thermal conductivity of from 70.3 to 427 W/m K, more typically from 70.3 to 405 W/m K and most typically from 70.3 to 90.5 W/m K. The channel coating 104 also has a thickness of from 0.0025 mm to 0.026 mm, more typically from 0.0025 mm to 0.0127 mm and most typically from 0.0051 mm to 0.0127 mm.

Additionally, it is to be appreciated that the electrode 52 can further include an anti-tarnishing layer disposed on the channel coating 104. The anti-tarnishing layer is a protective thin film organic layer that is applied on top of the channel coating 104. Protective systems such as Technic Inc.'s Tarniban™ can be used following the formation of the channel coating 104 of the electrode 52 to reduce oxidation of the metal in the electrode 52 and in the channel coating 104 without inducing excessive thermal resistance. For example, in one embodiment, the electrode 52 can comprise silver and the channel coating 104 can comprise silver with the anti-tarnishing layer present for providing enhanced resistance to the formation of deposits compared to pure silver. Typically, the electrode 52 comprises copper and the channel coating 104 comprises nickel for maximizing thermal conductivity and resistance to the formation of deposits, with the anti-tarnishing layer disposed on the channel coating 104.

Without being bound by theory, the delay of fouling attributed to the presence of the channel coating 104 extends the life of the electrode 52. Increasing the life of the electrode 52 decreases production cost as the electrode 52 needs to be replaced less often as compared to electrodes 52 without the channel coating 104. Additionally, the production time to deposit the material 22 on the carrier body 24 is also decreased because replacement of electrodes 52 is less frequent compared to when electrodes 52 are used without the channel coating 104. The channel coating 104 results in less down time for the manufacturing apparatus 20.

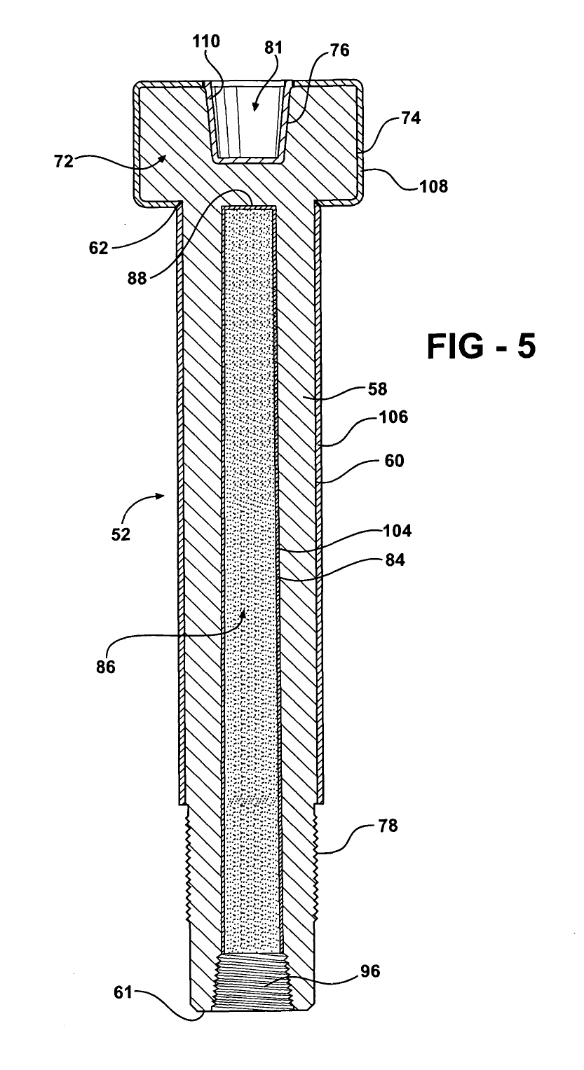

The electrode 52 can be coated in other locations other than the interior surface 84 for extending the life of the electrode 52. Referring to FIG. 5, in one embodiment the electrode 52 includes a shaft coating 106 disposed on the exterior surface 60 of the shaft 58. The shaft coating 106 extends from the head 72 to the first set of threads 78 on the shaft 58. The shaft coating 106 can comprise a second metal. For example, the shaft coating 106 can comprise at least one of silver, gold, nickel, and chromium. Typically, the shaft coating 106 comprises silver. The shaft coating 106 has a thickness of from 0.0254 mm to 0.254 mm, more typically from 0.0508 mm to 0.254 mm and most typically from 0.127 mm to 0.254 mm.

In one embodiment, the electrode 52 includes a head coating 108 disposed on the exterior surface 74 of the head 72. The head coating 108 generally comprises a metal. For example, the head coating 108 can comprise at least one of silver, gold, nickel, and chromium. Typically, the head coating 108 comprises nickel. The head coating 108 has a thickness of from 0.0254 mm to 0.254 mm, more typically from 0.0508 mm to 0.254 mm and most typically from 0.127 mm to 0.254 mm.

The head coating 108 can provide resistance to corrosion in a chloride environment during the harvesting of polycrystalline silicon and can further provide resistance to chemical attack via chlorination and/or silicidation as a result of the deposition of the material 22 on the carrier body 24. On copper electrodes, Cu₄Si and copper chlorides form, but for a nickel electrode, nickel silicide forms slower than copper silicide. Silver is even less prone to silicide formation.

In one embodiment, the electrode 52 includes a contact region coating 110 disposed on the external surface 82 of the contact region 76. The contact region coating 110 generally comprises a metal. For example, the contact region coating 110 can comprise at least one of silver, gold, nickel, and chromium. Typically, the contact region coating 110 comprises nickel or silver. The contact region coating 110 has a thickness of from 0.00254 to 0.254 mm, more typically from 0.00508 mm to 0.127 mm and most typically from 0.00508 mm to 0.0254 mm. Selection of the specific type of metal can depend on the chemical nature of the gas, thermal conditions in the vicinity of the electrode 52 due to a combination of the temperature of the carrier body 24, electrical current flowing through the electrode 52, cooling fluid flow rate, and cooling fluid temperature can all influence the choice of metals used for various sections of the electrode. For instance, the head coating 108 can comprise nickel or chromium due to chlorination resistance while the use of silver for the contact region coating 110 can be chosen for silicidation resistance over natural resistance to chloride attack.

The contact region coating 110 also provides improved electrical conduction and minimizes a copper silicide buildup within the contact region 76. The copper silicide buildup prevents a proper fit between the socket 57 disposed within the contact region 76 which can lead to a pitting of the socket 57. The pitting causes small electric arcs between the contact region 76 and socket 57 that results to metal contamination of the polycrystalline silicon product.

It is to be appreciated that the electrode 52 can have at least one of the shaft coating 106, the head coating 108 and the contact region coating 110 in any combination in addition to the channel coating 104. The channel coating 104, the shaft coating 106, the head coating 108 and the contact region coating 110 can be formed by electroplating. However, it is to be appreciated that each of the coatings can be formed by different methods without deviating from the subject invention. Also, it is to be appreciated by those skilled in the art of manufacturing high purity semiconductor materials, such as polycrystalline silicon, that some plating processes utilize materials that are dopants, e.g. Group III and Group V elements (excluding nitrogen for the case of manufacturing polycrystalline silicon), and choice of the appropriate coating method can minimize the potential contamination of the carrier body 24. For example, it is desired that areas of the electrode typically disposed within the chamber 32, such as the head coating 108 and the contact region coating 110, have minimal boron and phosphorous incorporation in their respective electrode coatings.

A typical method of deposition of the material 22 on the carrier body 24 is discussed below and refers to FIG. 6. The carrier body 24 is placed within the chamber 30 such that the sockets 57 disposed at the first end 54 and the second end 56 of the carrier body 24 are disposed within the cup 81 of the electrode 52 and the chamber 30 is sealed. The electrical current is transferred from the power supply device 90 to the electrode 52. A deposition temperature is calculated based on the material 22 to be deposited. The operating temperature of the carrier body 24 is increased by direct passage of the electrical current to the carrier body 24 so that the operating temperature of the carrier body 24 exceeds the deposition temperature. The gas 45 is introduced into the chamber 30 once the carrier body 24 reaches the deposition temperature. In one embodiment, the gas 45 introduced into the chamber 30 comprises a halosilane, such as a chlorosilane or a bromosilane. The gas can further comprise hydrogen. However it is to be appreciated that the instant invention is not limited to the components present in the gas and that the gas can comprise other deposition precursors, especially silicon containing molecular such as silane, silicon tetrachloride, and tribromosilane. In one embodiment, the carrier body 24 is a silicon slim rod and the manufacturing apparatus 20 can be used to deposit silicon thereon. In particular in this embodiment, the gas typically contains trichlorosilane and silicon is deposited onto the carrier body 24 as a result of the thermal decomposition of trichlorosilane. The coolant is utilized for preventing the operating temperature of the electrode 52 from reaching the deposition temperature to ensure that silicon is not deposited on the electrode 52. The material 22 is deposited evenly onto the carrier body 24 until a desired diameter of material 22 on the carrier body 24 is reached.

Once the carrier body 24 is processed, the electrical current is interrupted so that the electrode 52 and the carrier body 24 stop receiving the electrical current. The gas 45 is exhausted through the outlet 46 of the housing 28 and the carrier body 24 and the electrode 52 are allowed to cool. Once the operating temperature of the processed carrier body 24 has cooled the processed carrier body 24 can be removed from the chamber 30. The processed carrier body 24 is then removed and a new carrier body 24 is placed in the manufacturing apparatus 20.

Obviously, many modifications and variations of the present invention are possible in light of the above teachings. The foregoing invention has been described in accordance with the relevant legal standards; thus, the description is exemplary rather than limiting in nature. Variations and modifications to the disclosed embodiment may become apparent to those skilled in the art and do come within the scope of the invention. Accordingly, the scope of legal protection afforded this invention may only be determined by studying the following claims.

1. A manufacturing apparatus for deposition of a material on a carrier body having a first end and a second end spaced from each other with a socket disposed at each end of the carrier body, said apparatus comprising:
a housing defining a chamber;
an inlet defined through said housing for introducing a gas into said chamber;
an outlet defined through said housing for exhausting the gas from said chamber;
at least one electrode disposed through said housing with said electrode at least partially disposed within said chamber for receiving the socket and with said electrode having an interior surface defining a channel;
a power supply device coupled to said electrode for providing an electrical current to said electrode;
a circulation system disposed within said channel for circulating a coolant through said electrode; and
a channel coating disposed on said interior surface for maintaining thermal conductivity between said electrode and the coolant.

2. The apparatus as set forth in claim 1 wherein said at least one electrode includes a first electrode for receiving the socket at the first end of the carrier body and a second electrode for receiving the socket at the second end of the carrier body.

3. The apparatus as set forth in claim 1 wherein said electrode further includes a shaft and a head defining a contact region with said head disposed on said shaft.

4. The apparatus as set forth in claim 3 wherein said shaft has a first end and a second end and wherein said channel has a length extending between said first end and said second end of said electrode.

5. The apparatus as set forth in claim 4 wherein said circulating system includes an interior tube mounted within said first end of said electrode with said interior tube disposed within and extending a majority of said length of said channel.

6. The apparatus as set forth in claim 1 wherein said channel coating comprises at least one of silver, gold, nickel, and chromium.

7. The apparatus as set forth in claim 1 wherein said channel coating comprises nickel.

8. The apparatus as set forth in claim 7 wherein said electrode further comprises an anti-tarnishing layer disposed on said channel coating.

9. An electrode for use with a manufacturing apparatus to deposit a material onto a carrier body and to circulate a coolant through said electrode, said electrode comprising:
a shaft having a first end and a second end spaced from each other;
a head disposed on said second end of said shaft;
at least one of said shaft and said head including an interior surface defining a channel;
a channel coating disposed on said interior surface for maintaining thermal conductivity between said electrode and the coolant.

10. The electrode as set forth in claim 9 wherein said interior surface includes a terminal end spaced from said first end of said shaft.

11. The electrode as set forth in claim 10 wherein said shaft defines said channel.

12. The electrode as set forth in claim 9 wherein said head is integral to said shaft and said shaft and said head comprise copper.

13. The electrode as set forth in claim 9 wherein said head is integral to said shaft and said shaft and said head comprise oxygen-free electrolytic copper.

14. The electrode as set forth in claim 9 wherein said channel coating comprises at least one of silver, gold, nickel, and chromium.

15. The electrode as set forth in claim 9 wherein said channel coating comprises nickel.

16. The electrode as set forth in claim 15 further comprising an anti-tarnishing layer disposed on said channel coating.

17. The electrode as set forth in claim 9 wherein said shaft has an exterior surface disposed between said first end and said second end of said shaft.

18. The electrode as set forth in claim 17 further including a shaft coating disposed on said exterior surface of said shaft.

19. The electrode as set forth in claim 18 wherein said shaft coating comprises at least one of silver, gold, nickel, and chromium.

20. The electrode as set forth claim 18 wherein said shaft coating comprises silver.

21. The electrode as set forth in claim 9 wherein said head has an exterior surface.

22. The electrode as set forth in claim 21 further including a head coating disposed on said exterior surface of said head.

23. The electrode as set forth in claim 22 wherein said head coating comprises at least one of silver, gold, nickel, and chromium.

24. The electrode as set forth in claim 22 wherein said head coating comprises nickel.

25. The electrode as set forth in claim 9 wherein the carrier body has a first end and a second end spaced from each other with a socket disposed at each end of the carrier body.

26. The electrode as set forth in claim 25 wherein said exterior surface of said head defines a contact region for receiving the socket at the end of the carrier body.

27. The electrode as set forth in claim 26 further including a contact region coating disposed on said exterior surface of said contact region.

28. The electrode as set forth in claim 27 wherein said contact region coating comprises at least one of silver, gold, and chromium.

29. The electrode as set forth in claim 9 wherein said channel coating has a thermal conductivity of from 70.3 to 427 W/m K.

30. The electrode as set forth in claim 9 wherein said channel coating has a thickness of from 0.0025 mm to 0.026 mm.
